(19) United States
(12) Patent Application Publication
(10) Pub. No.: US 2025/0306138 A1
(43) Pub. Date: Oct. 2, 2025

(54) VERTICAL HALL ELEMENT

(71) Applicant: ABLIC Inc., Nagano (JP)

(72) Inventors: Satoshi SUZUKI, Nagano (JP); Shinji INAYOSHI, Nagano (JP)

(73) Assignee: ABLIC Inc., Nagano (JP)

(21) Appl. No.: 19/043,539

(22) Filed: Feb. 3, 2025

(30) Foreign Application Priority Data
Mar. 29, 2024 (JP) 2024-055281
Nov. 5, 2024 (JP) 2024-193545

(51) Int. Cl. G01R 33/07

(52) U.S. Cl. CPC G01R 33/077

(57) ABSTRACT

A vertical Hall element 100 includes: a P-type semiconductor substrate 10; an N-type epitaxial layer 30 formed on a surface of the P-type semiconductor substrate 10; an electrode group 110, disposed on a surface of the N-type epitaxial layer 30, the electrodes 111 to 115 being disposed linearly; a constant current source, causing a constant current to flow among the electrodes 111 to 115 of the electrode group 110; and a conductor 120, disposed to be overlapped with at least a portion of the current path of the constant current when viewed in a plan view, and able to be applied with a predetermined voltage.

### CROSS-REFERENCE TO RELATED APPLICATION

This application claims the priority benefit of Japan application serial no. 2024-055281, filed on Mar. 29, 2024 and Japan application serial no. 2024-193545, filed on Nov. 5, 2024. The entirety of each of the above-mentioned patent applications is hereby incorporated by reference herein and made a part of this specification.

### BACKGROUND

### Technical Field

The present invention relates to a vertical Hall element.

### Description of Related Art

Hall elements can be easily formed on the surface of a semiconductor substrate and are used, as magnetic sensors, for various purposes capable of position detection and angle detection in a contactless manner.

Among the Hall elements, horizontal Hall elements that detect magnetic field components perpendicular to the surface of the semiconductor substrate are generally well known. However, various proposals have also been made for vertical Hall elements that detect magnetic field components parallel to the surface of the semiconductor substrate.

For example, a vertical Hall element as follows is proposed: by using a structure in which a conductor plate where a predetermined potential is fixed is provided to cover an element surface, the detection accuracy as a Hall element can be maintained to be high, and and the noise resistance of the Hall element can be increased (see Japanese Patent Application Laid-open No. 2006-128400).

The invention provides a vertical Hall element capable of adjusting magnetic detection sensitivity.

### SUMMARY

A vertical Hall element according to an embodiment of the present invention includes: a semiconductor substrate, having a first conductivity type; an impurity diffusion layer, having a second conductivity type and formed on a surface of the semiconductor substrate; an electrode group, disposed on a surface of the impurity diffusion layer, wherein three or more electrodes are disposed linearly; a constant current source, causing a constant current to flow among the electrodes of the electrode group; and a conductor, disposed to be overlapped with at least a portion of the current path of the constant current when viewed in a plan view, and able to be applied with a predetermined voltage.

### BRIEF DESCRIPTION OF THE DRAWINGS

FIG. 1 is a schematic view illustrating a plane of a vertical Hall element according to the first embodiment of the invention.

FIG. 2 is a schematic view illustrating a cross-section of the vertical Hall element according to the first embodiment of the invention.

FIG. 3 is a schematic view illustrating a cross-section of the vertical Hall element according to the first embodiment of the invention.

FIG. 4 is a schematic view illustrating a plane of a vertical Hall element according to the second embodiment of the invention.

FIG. 5 is a schematic view illustrating a cross-section of the vertical Hall element according to the second embodiment of the invention.

FIG. 6 is a schematic view illustrating a plane of a vertical Hall element according to the third embodiment of the invention.

FIG. 7 is a schematic view illustrating a cross-section of the vertical Hall element according to the third embodiment of the invention.

FIG. 8 is a schematic view illustrating a cross-section of the vertical Hall element according to the fourth embodiment of the invention.

FIG. 9 is a schematic view illustrating a cross-section of the vertical Hall element according to the fifth embodiment of the invention.

### DESCRIPTION OF THE EMBODIMENTS

A vertical Hall element according to an embodiment of the present invention includes: a semiconductor substrate, having a first conductivity type; an impurity diffusion layer, having a second conductivity type and formed on a surface of the semiconductor substrate; an electrode group, disposed on a surface of the impurity diffusion layer, wherein three or more electrodes are disposed linearly; a constant current source, causing a constant current to flow among the electrodes of the electrode group; and a conductor, disposed to be overlapped with at least a portion of the current path of the constant current when viewed in a plan view, and able to be applied with a predetermined voltage.

According to an aspect of the present invention, a vertical Hall element capable of adjusting magnetic detection sensitivity can be provided.

The embodiments for implementing the present invention will be described in detail below with reference to the drawings.

In the drawings, the same reference numerals are assigned to the same structural parts, and repeated descriptions may be omitted. Also, in the drawings, the X direction, Y direction, and Z direction are orthogonal to each other. A direction including the X direction and the opposite direction (−X direction) of the X direction is referred to as the “X-axis direction”, the direction including the Y direction and the opposite direction (−Y direction) of the Y direction is referred to as the “Y-axis direction”, and the direction including the Z direction and the opposite direction (−Z direction, depth direction) of the Z direction is referred to as the “Z-axis direction” (height direction, thickness direction). In this regard, in the following embodiments, the Z-direction side surface of each film may be referred to as the “surface”.

The drawings are schematic, and the ratios of width, length, and depth are not necessarily as shown in the drawings.

In the following description, the first conductivity type is described as P-type, and the second conductivity type is described as N-type.

### First Embodiment

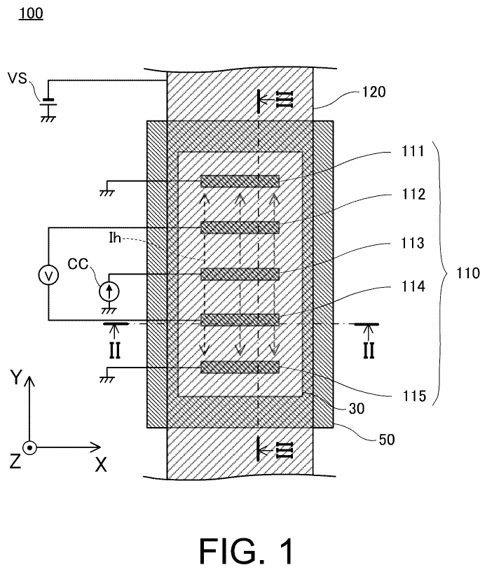

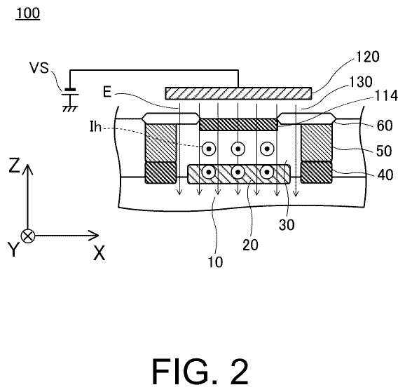

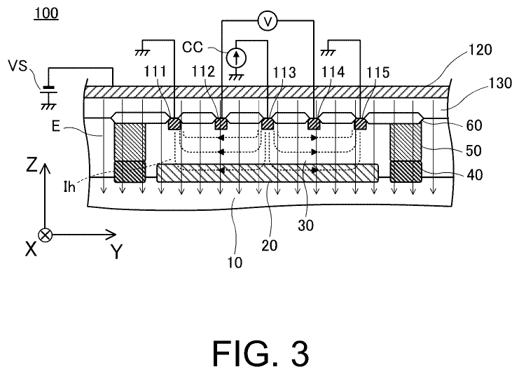

FIG. 1 is a schematic view illustrating a plane of a vertical Hall element according to the first embodiment of the invention. FIG. 2 is a schematic cross-sectional view taken along a line II-II of FIG. 1, and is a schematic view illustrating a cross-section of the vertical Hall element according to the first embodiment of the invention. FIG. 3 is a schematic cross-sectional view taken along a line III-III of FIG. 1, and is a schematic view illustrating a cross-section of the vertical Hall element according to the first embodiment of the invention.

A vertical Hall element 100 of the embodiment includes an electrode group 110, a P-type well layer 50 disposed around the outer periphery of the electrode group 110, and a conductor 120 disposed above the electrode group 110.

The electrode group 110 is a group of electrodes for the vertical Hall element 100 to serve as a magnetic sensor. The electrode group 110 is formed of five electrodes 111 to 115.

The electrodes 111 to 115 are disposed linearly on the surface of an N-type epitaxial layer 30, and are each formed in an N-type impurity region with a concentration higher than the N-type epitaxial layer 30. The electrodes 111 to 115 all have the same structure and are respectively rectangular when viewed in a plan view, and are arranged at equal intervals in a short-side direction thereof. As a result, the electrodes 111 to 115 have high structural symmetry. Thus, even when an external magnetic field is applied, the offset voltage that is output can be decreased.

In addition, the electrodes 111 to 115 are respectively connected to a voltage source, etc., and a necessary voltage is applied thereto through ON/OFF of switching elements connected to the respective electrodes.

For example, as illustrated in FIG. 1, the electrodes 111, 113, and 115 become drive current supply electrodes, while the electrodes 112 and 114 become Hall voltage output electrodes. In such case, a constant current source CC is connected to the electrode 113 at the center, and the electrodes 111, 115 are grounded. Accordingly, drive currents Ih flow in the +Y direction and the −Y direction, respectively, and current paths are as indicated by arrows in broken lines of FIG. 1. In response to the drive currents Ih, when an external magnetic field is applied in the +X direction, Lorentz forces are generated in the −Z direction for the electrons of the drive current Ih in the +Y direction, and in the +Z direction for the electrons of the drive current Ih in the −Y direction, resulting in Hall voltages with potential differences whose positive/negative properties are reversed. The vertical Hall element 100 can detect, with good sensitivity, the external magnetic field applied from the +X direction by outputting, as a Hall voltage, the voltage between the electrode 112 and the electrode 114, so as to add up the absolute values of the potential differences.

At the time of performing correction to remove the offset voltage by using the spinning current method, to obtain necessary output voltages, the drive current supply electrodes and the Hall voltage output electrodes may be interchanged.

The electrodes 114 and 115 are disposed to remove the offset voltage, and if the sole purpose is to detect the external magnetic field, three electrodes 111 to 113 may be sufficient.

Moreover, as shown in FIGS. 2 and 3, the vertical Hall element 100 is formed on the surface of the P-type semiconductor substrate 10 and includes an N-type buried layer 20, the N-type epitaxial layer 30 as an impurity diffusion layer, a P-type buried layer 40, a P-type well layer 50, and an insulating film 60. In addition, the vertical Hall element 100 further includes the conductor 120 and an interlayer insulating film 130.

The P-type semiconductor substrate 10 is a silicon wafer to which P-type impurities are added.

The N-type buried layer 20 is formed near the boundary between the P-type semiconductor substrate 10 and the N-type epitaxial layer 30, and is disposed below the electrode group 110. Since the impurity concentration of the N-type buried layer 20 is higher than the impurity concentration of the N-type epitaxial layer 30, the resistance value of the N-type buried layer 20 is lower than the resistance value of the N-type epitaxial layer 30, and the drive current Ih flows easily. Thus, regarding the current path of the drive current Ih, if there is a current path that flows downward through the N-type epitaxial layer 30, passes through the N-type buried layer 20, and then flows upward through the N-type epitaxial layer 30, there is also a current path that flows through the entire N-type epitaxial layer 30 without flowing through the N-type buried layer 20. Thus, the N-type buried layer 20 and the N-type epitaxial layer 30 become a current path of the drive current Ih at the time of operating as a magnetic sensor and serve as a magnetic sensing part.

The N-type epitaxial layer 30 is provided on the P-type semiconductor substrate 10, and N-type impurities are injected and diffused into the N-type epitaxial layer 30.

The impurity concentration of the N-type epitaxial layer 30 is constant in the embodiment. However, it may also be configured so that the impurity concentration increases as the depth increases. Accordingly, the impurity concentration gradient can be adjusted so that the resistance value of the deepest current path becomes similar to the resistance value of the current path passing through a shallow position. Thus, the current path can expand in a more balanced manner, and the magnetic detection sensitivity of the vertical Hall element 100 can be increased.

The P-type buried layer 40 is formed near the boundary between the P-type semiconductor substrate 10 and the N-type epitaxial layer 30. The P-type buried layer 40 is disposed at a location separate from the N-type buried layer 20 and is disposed to contact the bottom surface of the P-type well layer 50.

The P-type well layer 50 is formed for element isolation and, when viewed in a plan view, is arranged in a rectangular ring shape on the outer periphery separated from the electrode group 110. The P-type well layer 50 is formed deep enough to contact a P-type buried layer 40, which will be described later. As a result, the vertical Hall element 100 is electrically isolated from another region (not shown) on the P-type semiconductor substrate 10 on the periphery of the vertical Hall element 100. In the region on the P-type semiconductor substrate 10 that is electrically isolated from the vertical Hall element 100, elements such as transistors are provided to form at least one of a circuit for processing output signals from the vertical Hall element 100 and a circuit for supplying signals to the vertical Hall element 100.

Moreover, because the shape of the P-type well layer 50 is ring-shaped, the P-type well layer 50 can prevent the current from the electrode group 110 from diffusing, and the magnetic detection sensitivity and the removal accuracy of the offset voltage can be increased.

The insulating film 60 is a silicon oxide film formed on the surface of the N-type epitaxial layer 30 by performing a local oxidation of silicon (LOCOS) process. The insulating film 60 is provided on the periphery of the electrode group 110 and on the upper surface of the P-type well layer 50.

As the insulating film 60, for example, from the perspective that a depletion layer may occur near the surface if the insulating film 60 is a film having a conductivity type, such as a P-type electrode isolation diffusion layer, a material that does not possess a conductivity type may be used. The conductor 120 is a metal layer formed, inside the interlayer insulating film 130

formed on the upper surface of the insulating film 60 and the electrode group 110, to cover the entire region of the current path of the N-type epitaxial layer 30 and the N-type buried layer 20 surrounded by the P-type well layer 50. The conductor 120 is connected to a voltage source VS, and is applied with a “predetermined voltage”.

If the “predetermined voltage” is a “negative voltage”, an electrical field E as indicated by an arrow sign in FIG. 2 is applied to the N-type buried layer 20 and the N-type epitaxial layer 30 serving as the current path of the drive current Ih, and the carrier density of the N-type buried layer 20 and the N-type epitaxial layer 30 is reduced. As the carrier density decreases, the drive current Ih becomes more difficult to flow. Thus, the voltage applied from the constant current source CC where the current amount of the drive current Ih is constant to the electrode 113 increases, and the Lorentz force resulting from the external magnetic field in the electrons of the drive current Ih that flow rapidly increases. Thus, the magnetic detection sensitivity of the vertical Hall element 100 increases.

Meanwhile, if the “predetermined voltage” is a “positive voltage”, the electrical field E in a direction reverse to the arrow sign in FIG. 2 is applied to the N-type buried layer 20 and the N-type epitaxial layer 30, and the carrier density of the N-type buried layer 20 and the N-type epitaxial layer 30 increases. As the carrier density increases, the drive current Ih becomes easier to flow. Thus, the voltage applied from the constant current source CC where the current amount of the drive current Ih is constant to the electrode 113 decreases, and the Lorentz force resulting from the external magnetic field in the electrons of the drive current Ih that flow slowly decreases. Thus, the magnetic detection sensitivity of the vertical Hall element 100 decreases.

Consequently, the vertical Hall element 100 can adjust the magnetic detection sensitivity through the positivity/negativity and the magnitude of the “predetermined voltage” applied to the conductor 120.

In addition, the vertical Hall element 100 is in a size that the conductor 120 covers the entire region of the current path when viewed in a plan view. Therefore, the external noise entering from the top can be cut off.

While the conductor 120 is arranged as a metal layer in the embodiment, the conductor 120 may also be arranged as a high-concentration impurity conductor formed of polysilicon.

The interlayer insulating film 130 is formed over the entire upper surface of the insulating film 60 and the electrode group 110. In the embodiment, the interlayer insulating film 130 is a silicon oxide film to which phosphorus and boron are added (also referred to as a boro-phospho silicate glass (BPSG) film).

Next, the manufacturing method of the vertical Hall element in the embodiment will be described.

First, N-type impurities or P-type impurities are selectively injected into regions where the N-type buried layer 20 and the P-type buried layer 40 are to be formed in the P-type semiconductor substrate 10. Then, the N-type epitaxial layer 30 containing N-type impurities is formed thereon. By selectively injecting and diffusing P-type impurities into the surface of the N-type epitaxial layer 30, the P-type well layer 50 is formed. Then, by using the insulating film 60 formed by performing the LOCOS process on the surface of the N-type epitaxial layer 30 as a mask, N-type impurities are injected at a high concentration from the surface of the N-type epitaxial layer 30 to form the electrode group 110. Then, after being formed and planarized on the entire upper surface of the insulating film 60 and the electrode group 110, the conductor 120 of the metal layer is formed.

As described above, the vertical Hall element 100 can be formed.

In this way, the vertical Hall element 100 of the embodiment includes the constant current source CC and the conductor 120. The constant source CC causes a constant current to flow among the electrodes 111 to 115. The conductor 120 is disposed to be overlapped with at least a portion of the current path for the constant current when viewed in a plan view and able to be applied with the predetermined voltage.

Accordingly, in the vertical Hall element 100, when a negative voltage is applied to the conductor 120, the electrical field E as indicated by the arrow sign in FIG. 2 is applied, the carrier density of the current path decreases, and the drive current Ih becomes difficult to flow. Then, the voltage applied from the constant current source CC to the electrode 113 increases, and the electrons of the drive current Ih flowing rapidly easily receive the Lorentz force resulting from the external magnetic field. In addition, since the electrical field E is applied in the −Z direction to the current path, a Coulomb force in the +Z direction is added to the moving electrons of the drive current Ih, the current path of the drive current Ih is dispersed from the N-type buried layer 20 to the surface side of the N-type epitaxial layer 30, and the Lorentz force resulting from the external magnetic field is easily received. Accordingly, the magnetic detection sensitivity of the vertical Hall element 100 increases.

Meanwhile, when a positive voltage is applied to the conductor 120, the electrical field E is applied in a direction reverse to the arrow sign in FIG. 2, the carrier density of the current path increases, and the drive current Ih becomes easy to flow. Then, the voltage applied from the constant current source CC to the electrode 113 decreases, and the electrons of the drive current Ih flowing slowly becomes difficult to receive the Lorentz force resulting from the external magnetic field. In addition, since the electrical field E is applied in the +Z direction to the current path, a Coulomb force in the −Z direction is applied to the moving electrons of the drive current Ih, the current path of the drive current Ih is concentrated on the side of the N-type buried layer, and the Lorentz force resulting from the external magnetic field becomes difficult to receive. Accordingly, the magnetic detection sensitivity of the vertical Hall element 100 decreases.

Consequently, the vertical Hall element 100 can adjust the magnetic detection sensitivity through the positivity/negativity and the magnitude of the “predetermined voltage” applied to the conductor 120.

### Second Embodiment

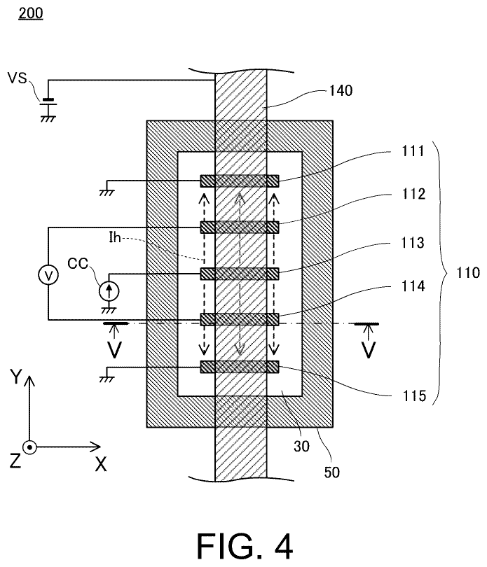

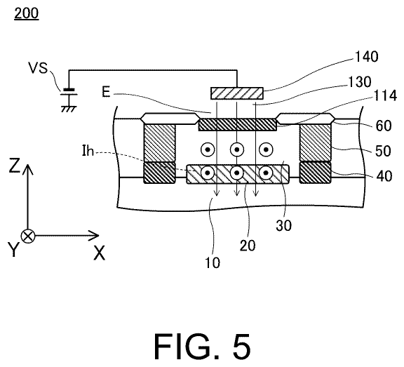

FIG. 4 is a schematic view illustrating a plane of a vertical Hall element according to the second embodiment of the invention. FIG. 5 is a schematic cross-sectional view taken along a line V-V of FIG. 4, and is a schematic view illustrating a cross-section of the vertical Hall element according to the second embodiment of the invention.

As shown in FIGS. 4 and 5, a vertical Hall element 200 in the embodiment is similar to the vertical Hall element 100, except that the conductor 120 in the vertical Hall element 100 is changed to a conductor 140 with a smaller width.

The following describes the conductor 140, which is a difference from the vertical Hall element 100.

The conductor 140 is a metal layer that is inside the interlayer insulating film 130 formed on the upper surface of the insulating film 60 and the electrode group 110 and is formed above the electrode group 110 to cover a portion of the electrode group 110. Like the conductor 120, the conductor 140 is connected to the voltage source VS, and is applied with the “predetermined voltage”.

Like the vertical Hall element 100, the vertical Hall element 200 configured in this way can adjust the magnetic detection sensitivity through the positivity/negativity and the magnitude of the “predetermined voltage” applied to the conductor 140.

In addition, the conductor 140 may also serve as a conductor that generates a bias magnetic field used for correction. In such case, in order to make the voltage distribution of the conductor 140 itself constant, a resistance element with high resistance is connected to a subsequent stage to cause a current to flow through the conductor 140.

### Third Embodiment

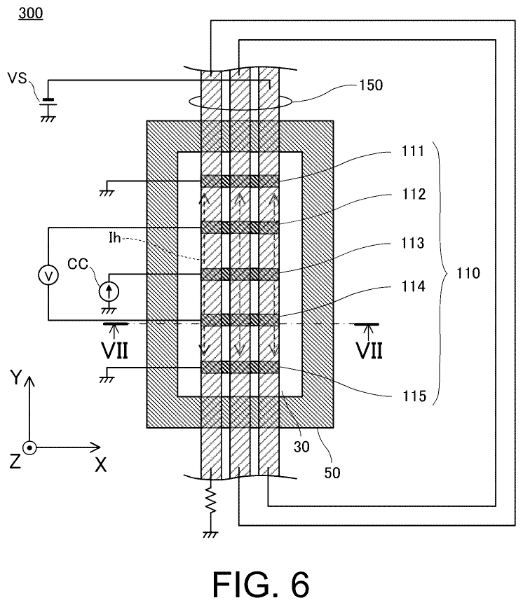

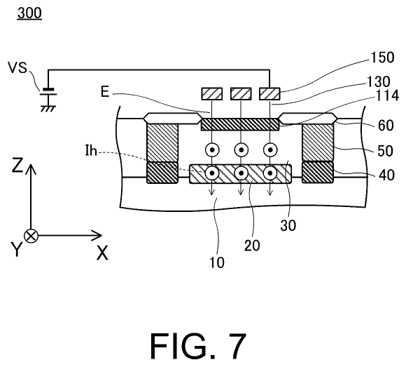

FIG. 6 is a schematic view illustrating a plane of a vertical Hall element according to the third embodiment of the invention. FIG. 7 is a schematic cross-sectional view taken along a line VII-VII of FIG. 6, and is a schematic view illustrating a cross-section of the vertical Hall element according to the third embodiment of the invention.

As shown in FIGS. 6 and 7, a vertical Hall element 300 in the embodiment is similar to the vertical Hall element 100, except that the conductor 120 in the vertical Hall element 100 is changed to a conductor 150 set with the width of the electrodes 111 to 115 and divided into three in the width direction.

The following describes the conductor 150, which is a difference from the vertical Hall element 100.

The conductor 150 is a metal layer that is inside the interlayer insulating film 130 formed on the upper surface of the insulating film 60 and the electrode group 110, arranged in a wound shape when viewed in a plan view, and is formed above the electrode group 10 so that a portion thereof covers the electrode group 110. In the conductor 150, an end in the wound shape is connected with the voltage source VS to be applied with the “predetermined voltage”, and the other end is connected with a resistance element having a high resistance and arranged so that a current flows through the conductor 150.

Like the vertical Hall element 100, the vertical Hall element 300 configured in this way can adjust the magnetic detection sensitivity through the positivity/negativity and the magnitude of the “predetermined voltage” applied to the conductor 150. In addition, since the conductor 150 is arranged in the wound shape, a bias magnetic field can be generated more efficiently than the conductor 140.

### Fourth Embodiment

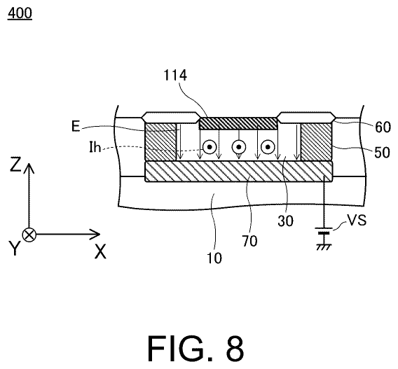

FIG. 8 is a schematic view illustrating a plane of a vertical Hall element according to the fourth embodiment of the invention.

As shown in FIG. 8, a vertical Hall element 400 in the embodiment is similar to the vertical Hall element 100, except that a P-type buried layer 70 is disposed in place of the N-type buried layer 20 and the P-type buried layer 40 in the vertical Hall element 100, and the function of the conductor 120 is possessed by the P-type buried layer 70.

The following describes the P-type buried layer 70 that is a point different from the vertical Hall element 100.

The P-type buried layer 70 is formed near the boundary between the P-type semiconductor substrate 10 and the N-type epitaxial layer 30, and is disposed below the electrode group 110 to contact the lower surface of the P-type well layer 50. The P-type buried layer 70 is connected to the voltage source VS, and is applied with the “predetermined voltage”.

The “predetermined voltage” in the fourth embodiment is the same as the “predetermined voltage” in the first embodiment.

Like the vertical Hall element 100, the vertical Hall element 400 configured in this way can adjust the magnetic detection sensitivity through the positivity/negativity and the magnitude of the “predetermined voltage” applied to the conductor 150.

### Fifth Embodiment

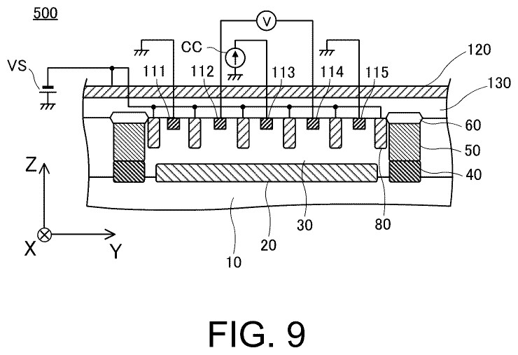

FIG. 9 is a schematic view illustrating a cross-section of a vertical Hall element according to the fifth embodiment of the invention.

As shown in FIG. 9, a vertical Hall element 500 in the embodiment is similar to the vertical Hall element 100, except that multiple second conductors 80 are disposed, in place of the insulating film 60 disposed above the N-type buried layer 20.

The following describes the second conductor 80, which is a difference from the vertical Hall element 100.

In the second conductor 80, a trench is formed on the surface of the N-type epitaxial layer 30, and P-type polysilicon is filled into the trench. In addition, although the second conductor 80 is at least formed among the electrodes 111 to 115 when viewed in a plan view, the second conductor 80 may also be configured to further surround the entirety of the electrodes 111 to 115. Accordingly, regarding the vertical Hall element 500, since the depletion layer can expand in a direction from a trench side surface toward each electrode in the N-type epitaxial layer 30, the adjustment width of sensitivity can be further expanded.

As described above, the vertical Hall element according to an embodiment of the present invention includes: a semiconductor substrate having a first conductivity type; an impurity diffusion layer having a second conductivity type and formed on the surface of the semiconductor substrate; and an electrode group disposed on the surface of the impurity diffusion layer, three or more electrodes being disposed linearly. In addition, the vertical Hall element includes a constant current source and a conductor. The constant current source causes a constant current to flow among electrodes in the electrode group. The conductor is disposed to be overlapped with at least a portion of the current path for the constant current when viewed in a plan view, and is able to be applied with a predetermined voltage.

Accordingly, the vertical Hall element can adjust the magnetic detection sensitivity through the positivity/negativity and the magnitude of the “predetermined voltage” applied to the conductor.

The present invention has been described with reference to specific embodiments. However, the present invention is not limited to these embodiments and can be modified in various ways within the scope of the present invention without departing from its spirit.

For example, while the first conductivity type has been described as P-type and the second conductivity type as N-type, the conductivity types can be interchanged. That is, the first conductivity type may be described as N-type and the second conductivity type may be described as P-type.

In addition, while the number of electrodes in the electrode group is set to five in each of the embodiments, the invention is not limited thereto. For example, in the case where the offset voltage can be lowered or accepted to the extent that removal of the offset voltage by the spinning current method is unnecessary, at least three electrodes consisting of two drive current supply electrodes and one Hall voltage output electrode are sufficient. In other words, with a configuration not forming the electrodes 114 and 115 of the vertical Hall element 100 shown in FIG. 1, etc., the layout area can be reduced, enabling miniaturization of the vertical Hall element.

In addition, in the respective embodiments, from the perspective of being able to easily manufacture, although the group of electrodes is described as being formed of N-type impurity regions having a higher concentration than the N-type epitaxial layer, the present invention is not limited thereto.

The electrode group may also be formed by a P-type high-concentration impurity conductor formed of polysilicon. When the electrode group is formed of polysilicon, the depletion on the side of the N-type epitaxial layer due to the work function difference between the P-type polysilicon and the N-type epitaxial layer can be used, and the sensitivity can be increased.

What is claimed is:

1. A vertical Hall element, comprising:
a semiconductor substrate, having a first conductivity type;
an impurity diffusion layer, having a second conductivity type and formed on a surface of the semiconductor substrate;
an electrode group, disposed on a surface of the impurity diffusion layer, wherein three or more electrodes are disposed linearly;
a constant current source, causing a constant current to flow among the electrodes of the electrode group; and
a first conductor, disposed to be overlapped with at least a portion of the current path of the constant current when viewed in a plan view, and able to be applied with a predetermined voltage.

2. The vertical Hall element as claimed in claim 1, wherein the first conductor is disposed above the electrode group.

3. The vertical Hall element as claimed in claim 2, wherein the first conductor is a metal layer or a high-concentration impurity conductor formed by polysilicon.

4. The vertical Hall element as claimed in claim 1, wherein the first conductor is a buried layer having the first conductivity type and disposed below the electrode group.

5. The vertical Hall element as claimed in claim 1, further comprising a second conductor disposed to be overlapped with at least a portion of the current path of the constant current when viewed in a cross-sectional view and formed by polysilicon having the first conductivity type.

6. The vertical Hall element as claimed in claim 1 wherein the first conductivity type is P-type, and the second conductivity type is N-type, and
the electrode group is formed by using a P-type high-concentration impurity conductor formed of polysilicon.
